(19) United States
(12) Patent Application Publication
(10) Pub. No.: US 2026/0231519 A1
(43) Pub. Date: Aug. 6, 2026

(54) SEMICONDUCTOR DEVICE AND FORMATION METHOD THEREOF

(71) Applicant: TAIWAN SEMICONDUCTOR MANUFACTURING COMPANY, LTD., Hsinchu (TW)

(72) Inventors: Jheng-Wei LIN, Hsinchu City (TW); Jet-Rung CHANG, Hsinchu County (TW)

(73) Assignee: TAIWAN SEMICONDUCTOR MANUFACTURING COMPANY, LTD., Hsinchu (TW)

(21) Appl. No.: 19/047,269

(22) Filed: Feb. 6, 2025

(51) Int. Cl. H10D 84/85; H10D 30/00; H10D 30/01; H10D 30/43; H10D 62/10; H10D 62/13; H10D 62/40; H10D 62/83; H10D 62/832; H10D 84/01

(52) U.S. Cl. CPC H10D 84/851; H10D 30/014; H10D 30/0191; H10D 30/43; H10D 30/502; H10D 62/121; H10D 62/151; H10D 62/405; H10D 62/83; H10D 62/832; H10D 84/017; H10D 84/0188

(57) ABSTRACT

A method comprises the following steps. A channel region is formed over a substrate, wherein the substrate has a (110) surface orientation and a trench in the substrate. An epitaxial growth is performed to the substrate to form epitaxial source/drain regions on opposite sides of the channel region, wherein first epitaxial patterns are formed on the sidewall of the trench during the epitaxial growth, wherein one of the first epitaxial patterns comprises a triangular shape. A gate is formed surrounding the channel region.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of GAA-FETs (e.g., nanowire FETs, nanosheet FETs, or the like) in a three-dimensional view, in accordance with some embodiments.

FIG. 2 illustrates a top view of a wafer according to various embodiments of the present disclosure.

FIG. 3 illustrates an enlarged top view of a portion of the wafer of FIG. 2 according to various embodiments of the present disclosure.

FIGS. 4, 5A, 6, 7, 8A, 10A, 14C, 15A, 16A, 17A and 18A are cross-sectional views at intermediate fabrication stages, illustrating reference cross-section A-A′ illustrated in FIG. 1 that extends through a gate region along a longitudinal axis of the gate region.

FIGS. 8B, 9B, 10B, 11B, 12B, 13B, 14B, 15B, 16B, 17B and 18B are cross-sectional views at intermediate fabrication stages, illustrating reference cross-section B-B′ illustrated in FIG. 1 that extends through a gate region along a longitudinal axis of the gate region.

FIGS. 9A, 10A, 11A, 12A, 13A, 14A and 15C illustrate reference cross-section C-C′ illustrated in FIG. 1 that extends through source/drain regions along the longitudinal direction of the gate region.

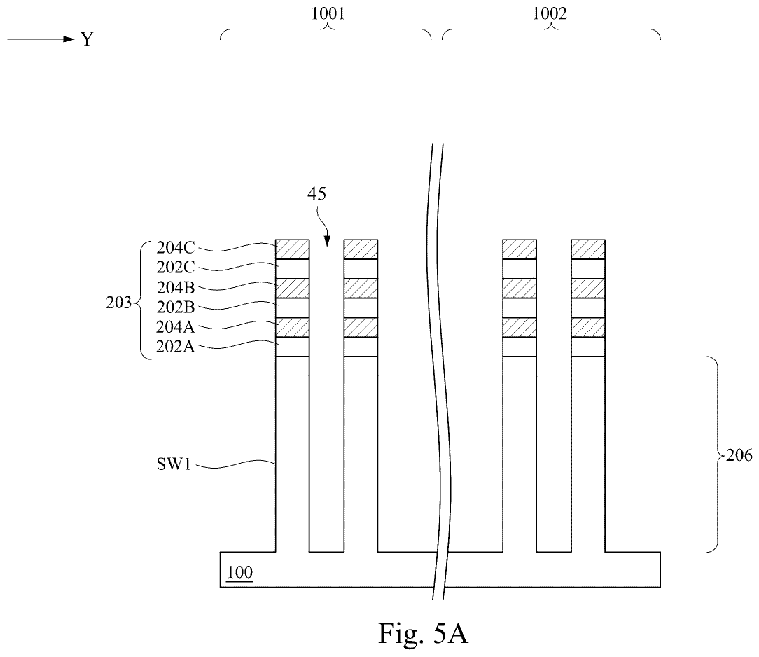

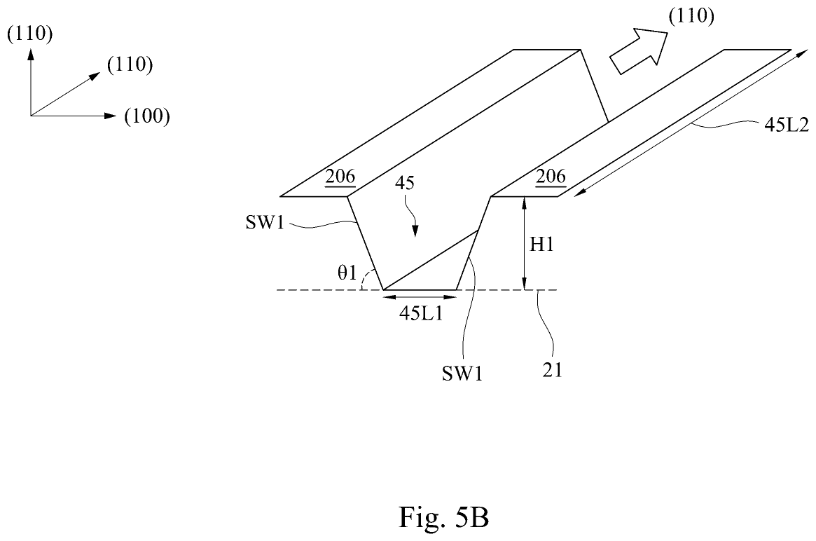

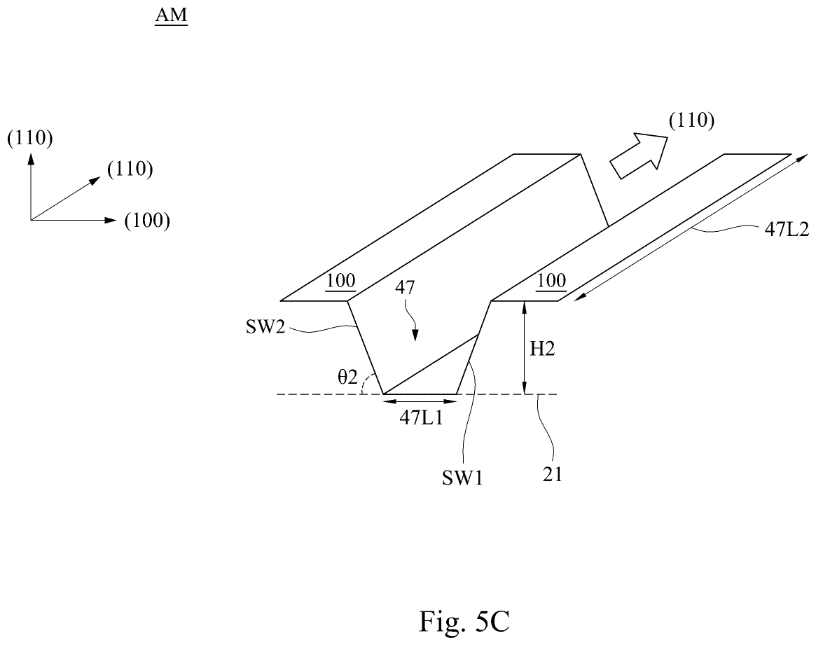

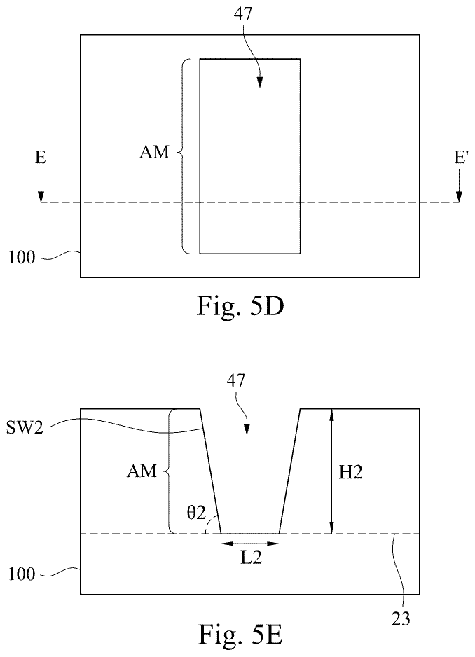

FIG. 5B is a perspective view of the trench between two adjacent fin structures in accordance with some embodiments.

FIG. 5C is a perspective view of a trench of an alignment mark in accordance with some embodiments.

FIG. 5D is a top view of FIG. 5C.

FIG. 5E is a cross-sectional view along line E-E′ of FIG. 5D in accordance with some embodiments.

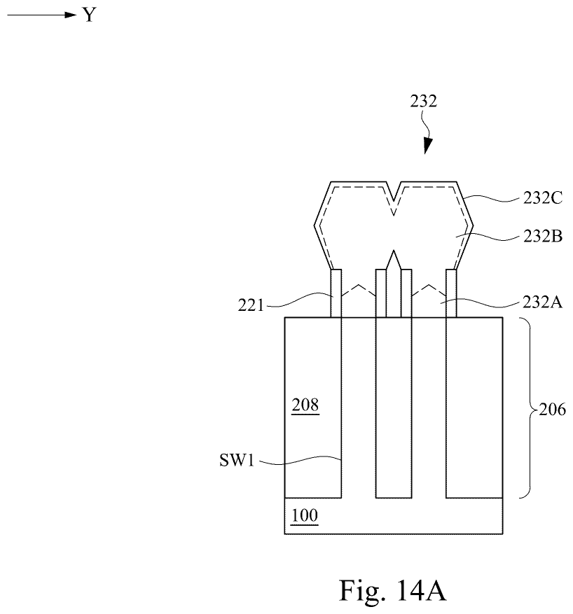

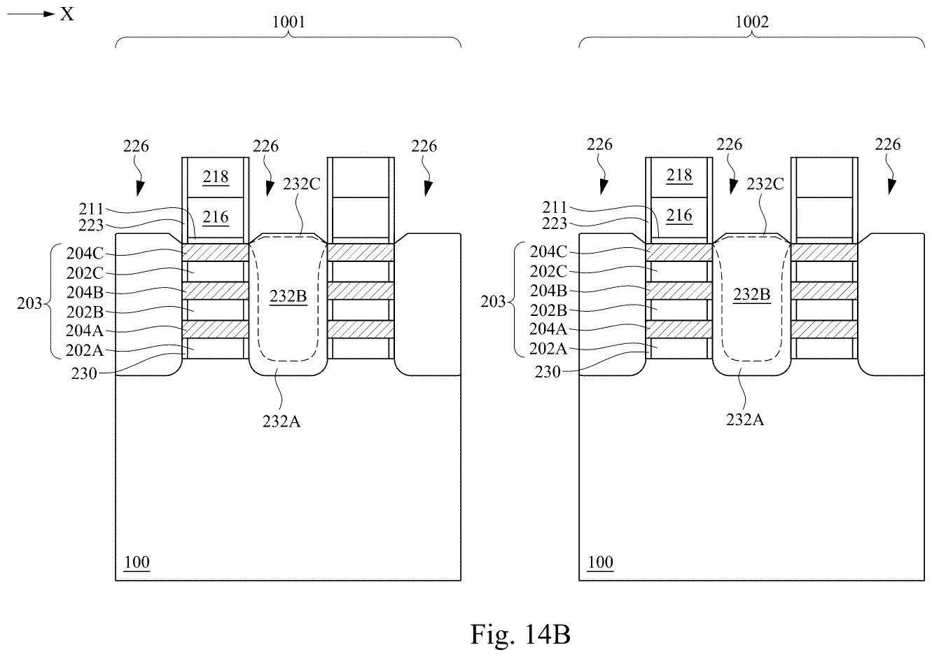

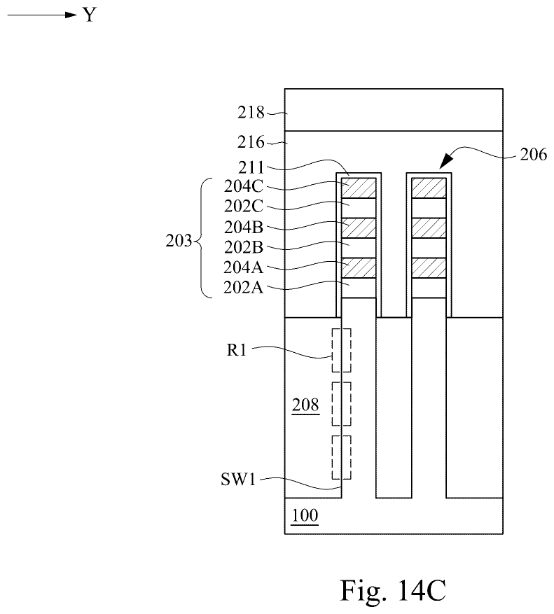

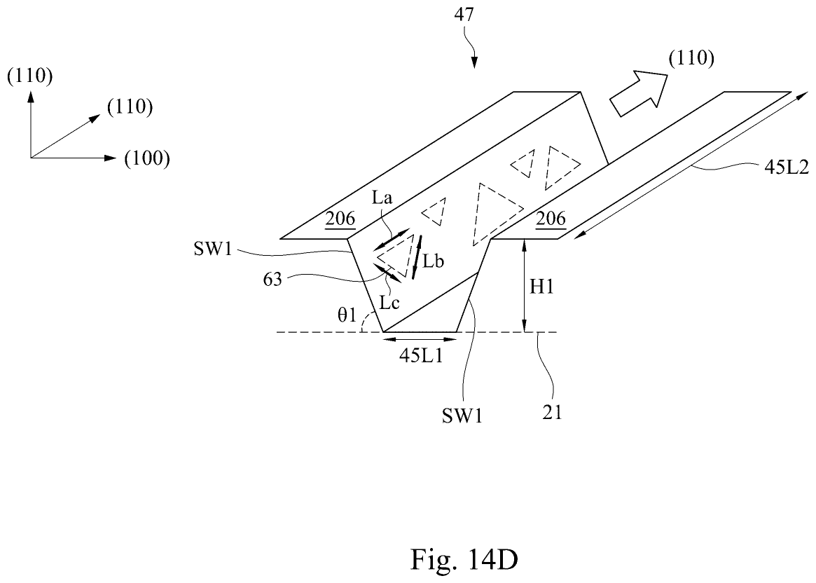

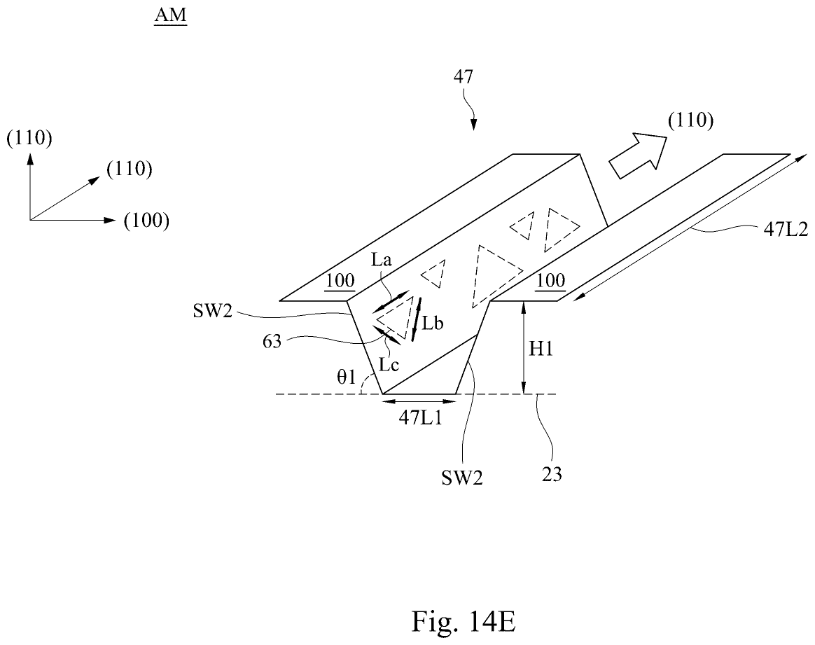

FIG. 14D is a perspective view of a trench between two adjacent fin structures in accordance with some embodiments.

FIG. 14E is a perspective view of the trench of the alignment mark in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated. In this disclosure, a source/drain refers to a source and/or a drain. It is noted that in the present disclosure, a source and a drain are interchangeably used and the structures thereof are substantially the same.

In semiconductor device manufacturing, wafers with a (100) surface orientation are commonly used, where the top surface of the wafer lies in the (100) plane. However, p-type devices fabricated on such wafers often experience reduced carrier mobility.

The present disclosure, in various embodiments, provides a method for manufacturing semiconductor devices using wafers with a (110) surface orientation, where the top surface of the wafer is in the (110) plane, also referred to as (110) wafers. Utilizing (110) wafers for transistor formation enhances the mobility of p-type devices, thereby improving the overall performance of devices such as Ring Oscillators (RO).

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to a metal-oxide-semiconductor (MOS) field-effect transistor (FET) device such as gate-all-around (GAA) transistor, fin field effect transistor (FinFET), and Complementary Field-Effect Transistor (CFET) structure including a substrate having a (110) surface orientation, with a top surface of the substrate in a (110) plane to boost the mobility of the p-type device. In addition, the embodiments of the disclosure may also be applied to a variety of metal oxide semiconductor transistors.

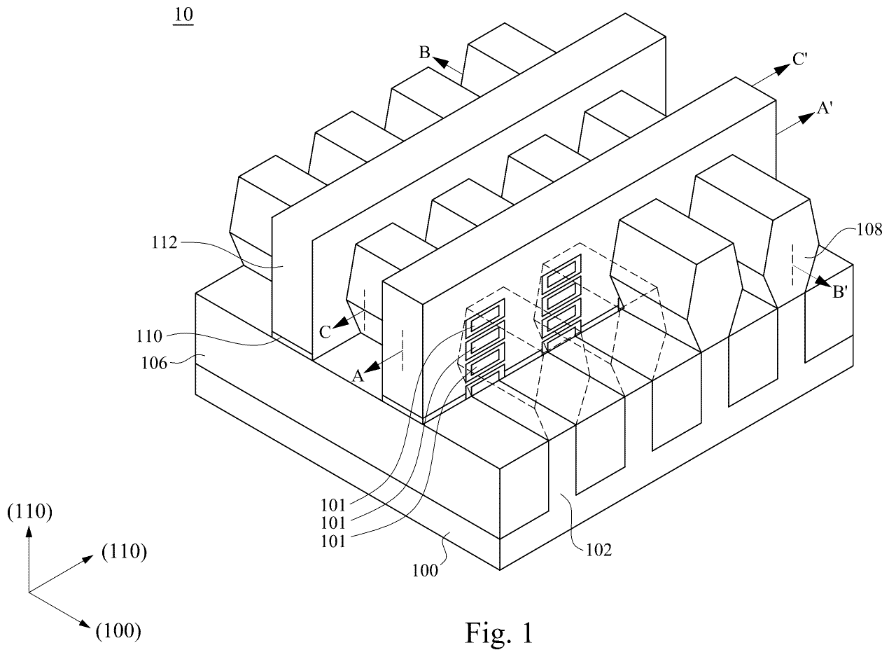

FIG. 1 illustrates an example of GAA-FETs (e.g., nanowire FETs, nanosheet FETs, or the like) 10 in a three-dimensional view, in accordance with some embodiments. In some embodiments, the GAA-FETs 10 may be used as a ring oscillator (RO) which is an electronic oscillator consisting of an odd number of inverters (or NOT gates) connected in a series, with the output of the last inverter fed back to the input of the first. This configuration creates a feedback loop that generates a periodic oscillating signal. The frequency of oscillation is determined by the number of inverters and the propagation delay through each inverter.

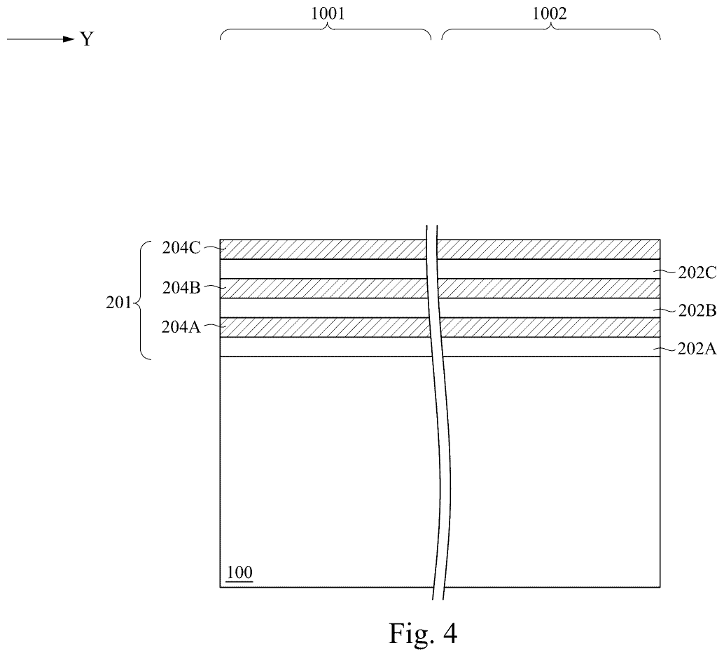

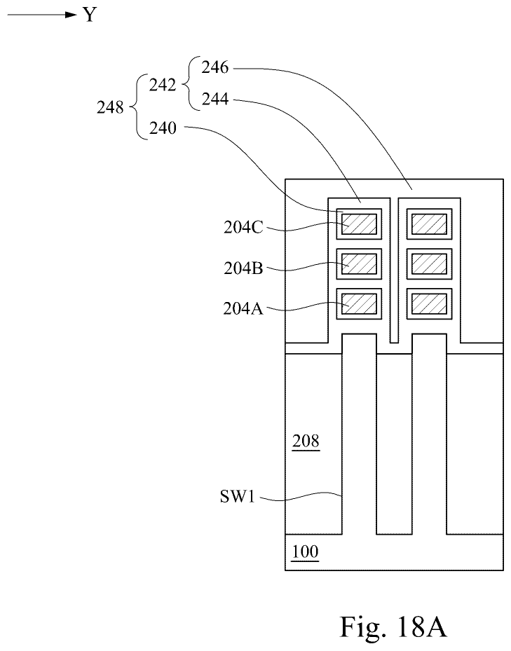

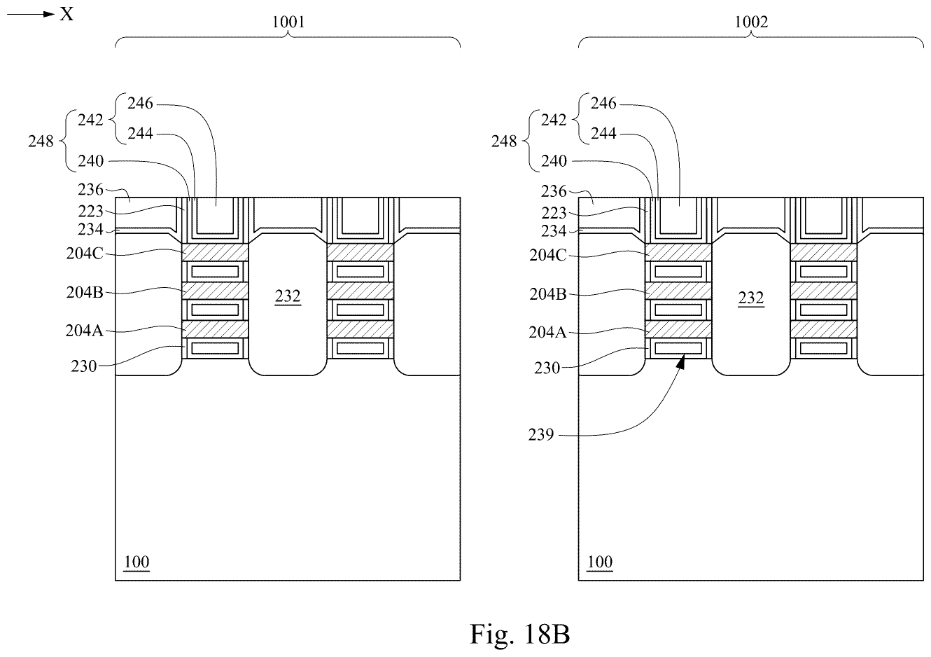

The GAA-FETs 10 comprise nanostructures 101 (e.g., nanosheets, nanowires, nanorings, nanoslabs, or other structures having nano-scale size (e.g., a few nanometers)) over fins 102 on a substrate 100 (e.g., a semiconductor substrate), wherein the nanostructures 101 act as channel regions for the GAA-FETs. As shown, the coordinate system includes an X-axis, Y-axis, and Z-axis. In some embodiments, the substrate 100 has (110) surface orientation. That is, the Y-axis may be referred to as (110) direction, the X-axis may be referred to as (100) direction and the Z-axis may be referred to as (110) direction. The substrate 100 with the (110) surface orientation can be used to control the orientation of the layers (e.g., the multi-layer stack 201 in FIG. 4) which are formed above the substrate 100. For example, first semiconductor layers 202A-C (collectively referred to as first semiconductor layers 202) and second semiconductor layers 204A-C (collectively referred to as second semiconductor layers 204) formed on the (110) surface orientation substrate 100 also can have (110) surface orientation. The first semiconductor layers 202A-C with (110) surface orientation can act as channel layers (i.e., channel regions or active regions) (see FIGS. 18A and 18B) and improves device performance due to a higher hole mobility on <100>/(110) than <110>/(100) and <110>/(110). By using such channel layers for the nano-FETs as ring oscillators (RO), the RO's performance can be enhanced by increasing the charge carrier mobility in the channel layers used for the inverters. In some embodiments, the substrate 100 is on a wafer having a notch directed at the <110> direction.

The nanostructure 101 may include p-type nanostructures, n-type nanostructures, or a combination thereof. Isolation regions 106 are disposed between adjacent fins 102, which may protrude above and from between neighboring isolation regions 106. Although the isolation regions 106 are described/illustrated as being separate from the substrate 100, as used herein, the term “substrate” may refer to the semiconductor substrate alone or a combination of the semiconductor substrate and the isolation regions. Additionally, although a bottom portion of the fins 102 are illustrated as being single, continuous materials with the substrate 100, the bottom portion of the fins 102 and/or the substrate 100 may comprise a single material or a plurality of materials. In this context, the fins 102 refer to the portion extending between the neighboring isolation regions 106.

Gate dielectrics 110 are over top surfaces of the fins 102 and along top surfaces, sidewalls, and bottom surfaces of the nanostructures 101. Gate electrodes 112 are over the gate dielectrics 110. Epitaxial source/drain regions 108 are disposed on the fins 102 on opposing sides of the gate dielectrics 110 and the gate electrodes 112.

FIG. 1 further illustrates reference cross-sections that are used in later figures. Cross-section A-A′ is along a longitudinal axis of a gate electrode 112 and in a direction, for example, perpendicular to the direction of current flow between the epitaxial source/drain regions 108 of a GAA-FET. That is, the cross-sectional A-A′ is along the y-axis. Cross-section B-B′ is perpendicular to cross-section A-A′ and is parallel to a longitudinal axis of a fin 102 of the GAA-FET and in a direction of, for example, a current flow between the epitaxial source/drain regions 108 of the GAA-FET. That is, the cross-sectional B-B′ is along the x-axis. Cross-section C-C′ is parallel to cross-section A-A′ and extends through epitaxial source/drain regions of the GAA-FETs. That is, the cross-sectional C-C′ is along the y-axis. Subsequent figures refer to these reference cross-sections for clarity. Some embodiments discussed herein are discussed in the context of GAA-FETs formed using a gate-last process. In other embodiments, a gate-first process may be used.

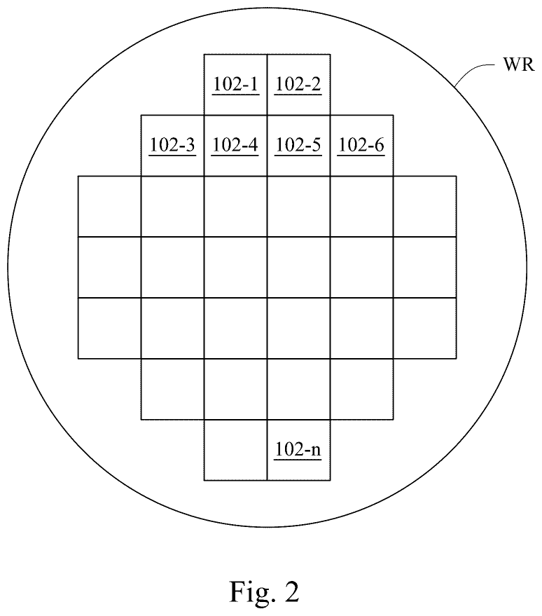

FIG. 2 illustrates a top view of a wafer according to various embodiments of the present disclosure. With reference to FIG. 2, a wafer WR includes a substrate (e.g., a semiconductor substrate) on which processing is conducted to produce layers of material, pattern features, and/or integrated circuits. As illustrated in FIG. 2, the wafer WR is divided into one or more fields 102. The wafer WR is divided into exposure fields 102-1, 102-2, 102-3, 102-4, 102-5, 102-6, . . . and 102-n. An exposure field includes an area of a substrate covered (e.g., exposed) by a single exposure process. So, when the wafer WR is subjected to a lithography process, a single exposure process may be used to transfer a pattern to each field (i.e., 102-1, 102-2, . . . 102-n) to form integrated circuits within each field.

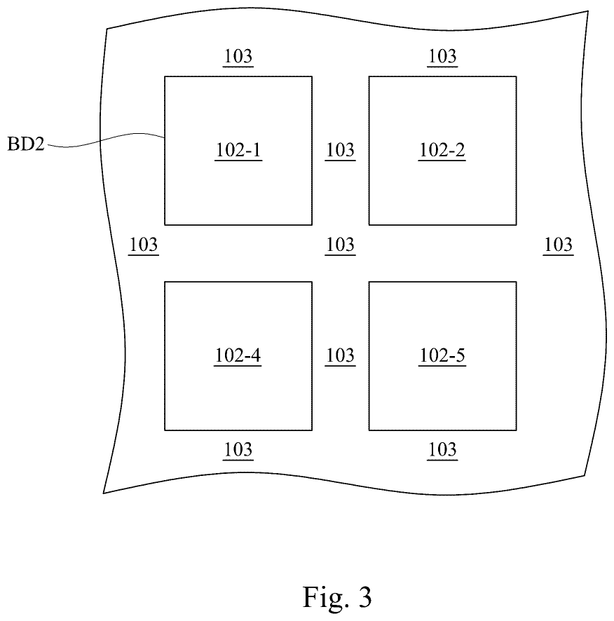

FIG. 3 illustrates an enlarged top view of a portion of the wafer of FIG. 2 according to various embodiments of the present disclosure. FIG. 3 illustrates a magnified portion of the wafer WR containing fields 102-1, 102-2, 102-4, and 102-5. The fields 102 are separated or defined by scribe lines (or lanes) 103. In the present embodiment, the scribe lines 103 are configured between each field 102-1, 102-2, 102-4, and 102-5 to identify a perimeter of each field 102-1, 102-2, 102-4, and 102-5. When each field 102-1, 102-2, 102-4, and 102-5 is exposed, one or more dies (chips) are patterned within the field. The fields 102-1, 102-2, 102-4, and 102-5 and the corresponding scribe lines 103 may include boundaries BD2 therebetween. During subsequent formation of source/drain epitaxial structures 232 (see FIG. 14A), epitaxial patterns with triangular profiles may be formed on the boundaries BD2, which will be discussed in greater detail below.

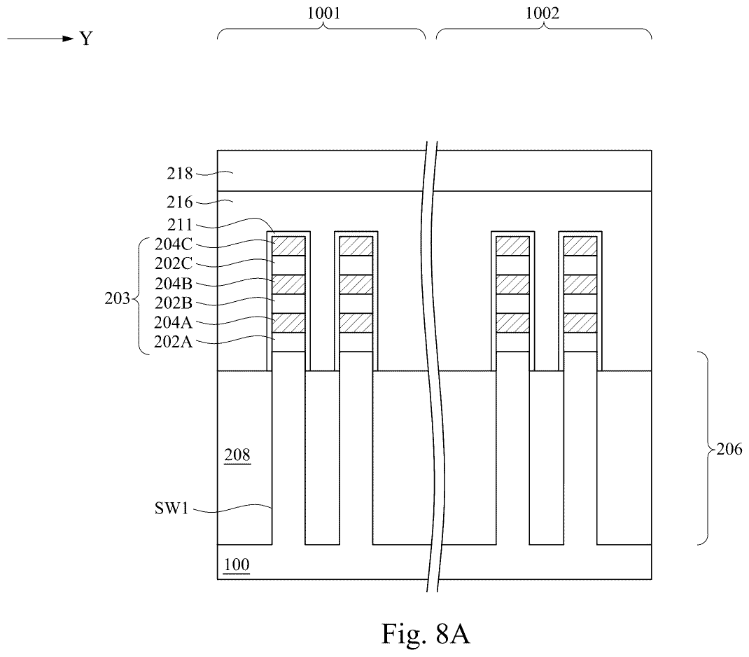

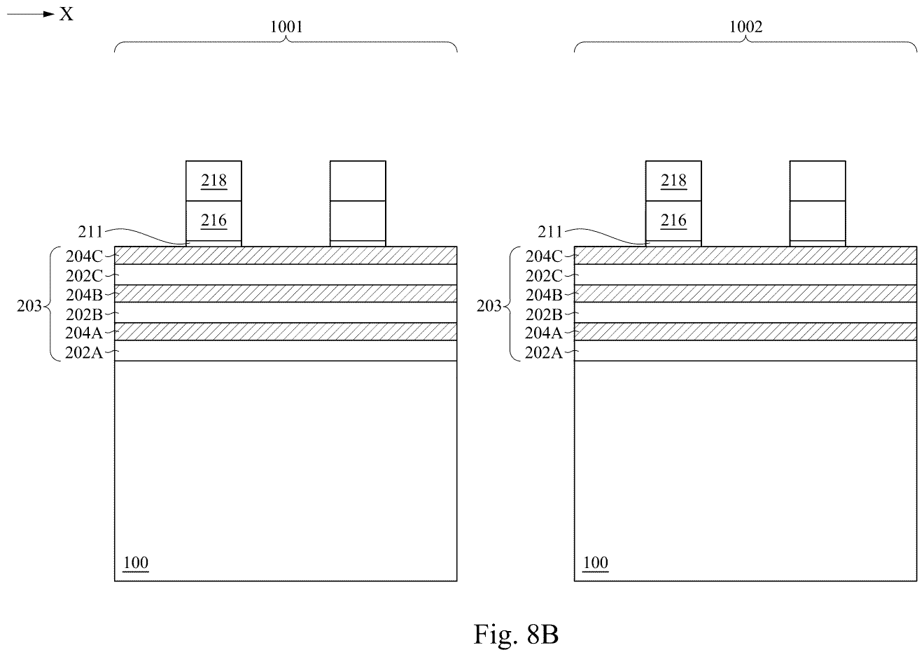

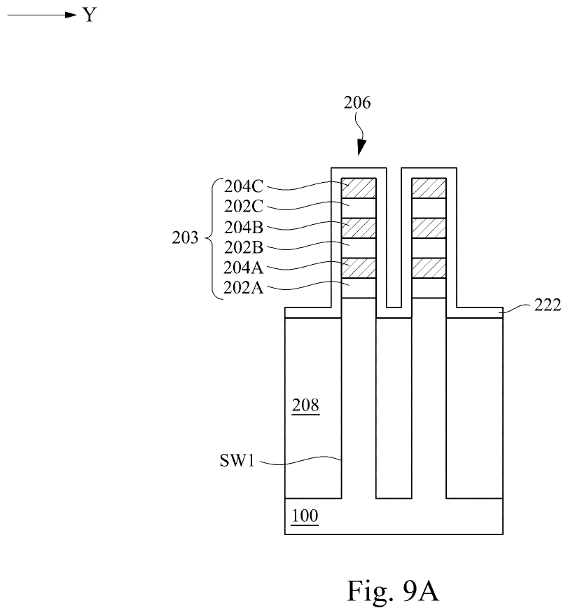

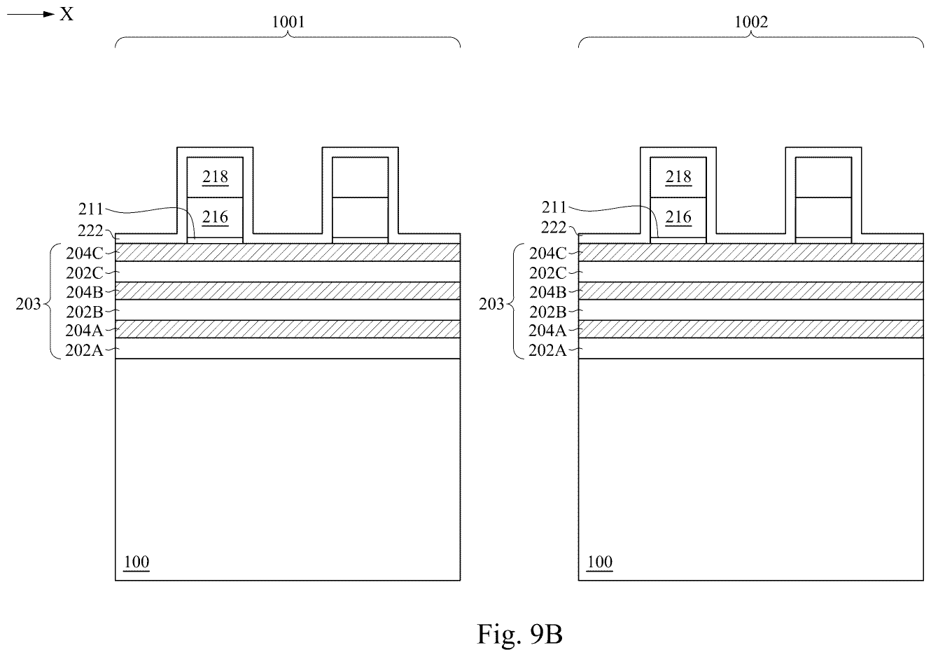

FIGS. 4, 5A, 6, 7, 8A, 10A, 14C, 15A, 16A, 17A and 18A are cross-sectional views at intermediate fabrication stages, illustrating reference cross-section A-A′ illustrated in FIG. 1 that extends through a gate region along a longitudinal axis of the gate region. FIGS. 8B, 9B, 10B, 11B, 12B, 13B, 14B, 15B, 16B, 17B and 18B are cross-sectional views at intermediate fabrication stages, illustrating reference cross-section B-B′ illustrated in FIG. 1 that extends through a gate region along a longitudinal axis of the gate region. FIGS. 9A, 10A, 11A, 12A, 13A, 14A and 15C illustrate reference cross-section C-C′ illustrated in FIG. 1 that extends through source/drain regions along the longitudinal direction of the gate region. FIG. 5B is a perspective view of the trench between two adjacent fin structures in accordance with some embodiments. FIG. 5C is a perspective view of a trench of an alignment mark in accordance with some embodiments. FIG. 5D is a top view of FIG. 5C. FIG. 5E is a cross-sectional view along line E-E′ of FIG. 5D in accordance with some embodiments. FIG. 14D is a perspective view of a trench between two adjacent fin structures in accordance with some embodiments. FIG. 14E is a perspective view of the trench of the alignment mark in accordance with some embodiments.

Reference is made to FIG. 4. For example, a substrate 100 may be a portion of the filed 102-1 of the wafer for forming nano-FETs. In some embodiments, the nano-FETs may be used as a ring oscillator (RO) which is an electronic oscillator consisting of an odd number of inverters (or NOT gates) connected in a series, with the output of the last inverter fed back to the input of the first. This configuration creates a feedback loop that generates a periodic oscillating signal. The frequency of oscillation is determined by the number of inverters and the propagation delay through each inverter. The substrate 100 may be a semiconductor substrate, such as a bulk semiconductor, a semiconductor-on-insulator (SOI) substrate, or the like, which may be doped (e.g., with a p-type or an n-type impurity) or undoped. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like. The alloy semiconductor may have a gradient SiGe feature in which the Si and Ge composition change from one ratio at one location to another ratio at another location of the gradient SiGe feature. The alloy SiGe may be formed over a silicon substrate. The SiGe substrate may be strained. Furthermore, the semiconductor substrate may be a semiconductor on insulator (SOI). In some examples, the semiconductor substrate may include a doped epi layer. In some examples, the silicon substrate may include a multilayer compound semiconductor structure.

The substrate 100 has a first device region 1001 and a second device region 1002. The first device region 1001 is a region in which first transistors will reside, and the second device region 1002 is a region in which second transistors will reside. In some embodiments, the first transistors are different from the second transistors at least in conductivity type. For example, the first device region 1001 can be for forming n-type devices, such as NMOS transistors, e.g., n-type GAA-FETs, and the second device region 1002 can be for forming p-type devices, such as PMOS transistors, e.g., p-type GAA-FETs.

The first device region 1001 may be separated from the second device region 1002, and any number of device features (e.g., other active devices, doped regions, isolation structures, etc.) may be disposed between the first device region 1001 and the second device region 1002. Although one first device region 1001 and one second device region 1002 are illustrated, any number of first device regions 1001 and second device regions 1002 may be provided.

Further in FIG. 4, a multi-layer stack 201 is formed over the substrate 100. The multi-layer stack 201 includes alternating layers of first semiconductor layers 202A-C (collectively referred to as first semiconductor layers 202) and second semiconductor layers 204A-C (collectively referred to as second semiconductor layers 204). For purposes of illustration and as discussed in greater detail below, the first semiconductor layers 202 will be removed and the second semiconductor layers 204 will be patterned to form channel regions of GAA-FETs.

The multi-layer stack 201 is illustrated as including three layers of each of the first semiconductor layers 202 and the second semiconductor layers 204 for illustrative purposes. In some embodiments, the multi-layer stack 201 may include any number of the first semiconductor layers 202 and the second semiconductor layers 204. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of GAA-FETs, such as silicon, silicon carbon, silicon germanium, or the like. The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of GAA-FETs.

Referring now to FIG. 5A, fin structures 206 are formed in the substrate 100 and nanostructures 203 are formed in the multi-layer stack 201, in accordance with some embodiments. In some embodiments, the nanostructures 203 and the fin structures 206 may be formed in the multi-layer stack 201 and the substrate 100, respectively, by etching trenches in the multi-layer stack 201 and the substrate 100. Each fin structure 206 and overlying nanostructures 203 can be collectively referred to as a fin extending from the substrate 100. The etching may be any acceptable etch process, such as a reactive ion etch (RIE), neutral beam etch (NBE), the like, or a combination thereof. The etching may be anisotropic. Forming the nanostructures 203 by etching the multi-layer stack 201 may further define first nanostructures 202A-C (collectively referred to as the first nanostructures 202) from the first semiconductor layers 202 and define second nanostructures 204A-C (collectively referred to as the second nanostructures 204) from the second semiconductor layers 204. The first nanostructures 202 and the second nanostructures 204 may further be collectively referred to as nanostructures 203.

The fin structures 206 and the nanostructures 203 may be patterned by any suitable method. For example, the fin structures 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 206.

FIG. 5A illustrates the fin structures 206 in the first device region 1001 and the second device region 1002 as having substantially equal widths for illustrative purposes. In some embodiments, widths of the fin structures 206 in the first device region 1001 may be greater or thinner than the fin structures 206 in the second device region 1002. Further, while each of the fin structures 206 and the nanostructures 203 are illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

In FIGS. 5A-5B, trenches 45 can be formed between adjacent fin structures 206. The fin structures 206 can have sidewalls SW1 facing the trench 45. During a subsequent formation of source/drain epitaxial structures 232, epitaxial patterns with triangular shapes may develop on the sidewalls SW1. This phenomenon occurs due to the inherent characteristics of the (110) surface orientation of the substrate 100. In some embodiments, the trenches 45 each may include a height H1 of about 50 nm to about 500 nm and a length 45L1 of about 50 nm to about 500 nm. In some embodiments, the sidewalls SW1 can be tapered. For example, a tapered angle θ1 of each of the sidewalls SW1 with respect to a line 21 parallel to a surface of the substrate 100 can be about 20° to about 70°.

In FIGS. 5C-5E, in some embodiments, the substrate 100 may include alignment marks AM disposed over a first side (e.g., front side) of the substrate 100. In some embodiments, in a top view, profiles of the alignment marks AM may be rectangular, as shown in FIG. 5D. In some other embodiments, the profiles of the alignment marks AM may be square, polygonal, round, elliptical, strip-shaped, T-shaped, L-shaped, box-shaped, cross-shaped or any suitable shape. In some embodiments, the alignment marks AM can be made of trenches 47 in the substrate 100. For example, the trenches 47 each may include a height H2 of about 50 nm to about 500 nm and a length 47L2 of about 50 nm to about 500 nm. In some embodiments, the trench 47 can include sidewalls SW2 which are tapered. For example, a tapered angle θ2 of each of the sidewalls SW2 with respect to a line 23 parallel to a surface of the substrate 100 can be about 20° to about 70°. The length 47L2 of the trench 47 can extend along a (110) direction.

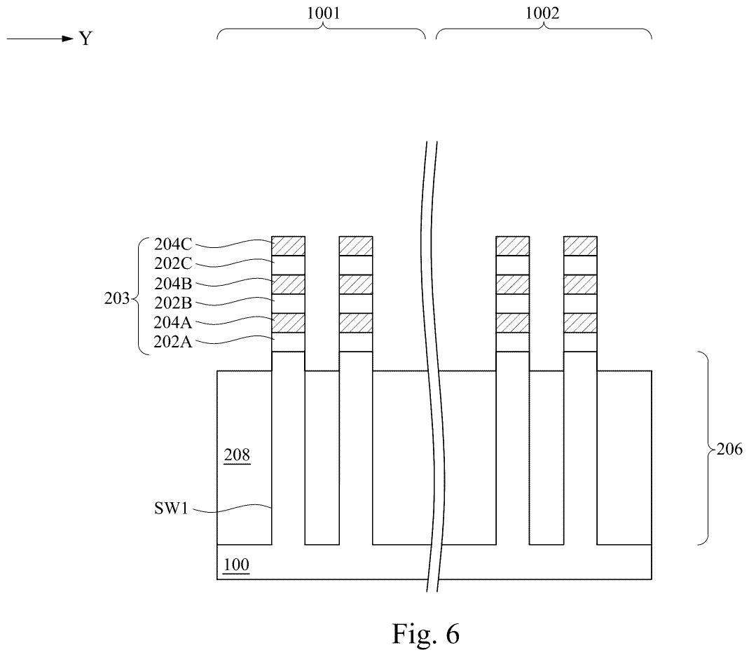

In FIG. 6, shallow trench isolation (STI) regions 208 are formed adjacent the fin structures 206. The STI regions 208 may be formed by depositing an insulation material over the substrate 100, the fin structures 206, and nanostructures 203, and between adjacent fin structures 206. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100, the fin structures 206, and the nanostructures 203. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI regions 208. The insulation material is recessed such that upper portions of fin structures 206 in the first and second device regions 1001 and 1002 and protrude from between neighboring STI regions 208. Further, the top surfaces of the STI regions 208 may have a flat surface as illustrated, a convex surface, a concave surface (such as dishing), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etches the material of the insulation material at a faster rate than the material of the fin structures 206 and the nanostructures 203). For example, an oxide removal using, for example, dilute hydrofluoric (dHF) acid may be used.

The process described above with respect to FIGS. 2 through 4 is just one example of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers (and resulting nanostructures 202) and the second semiconductor layers (and resulting nanostructures 204) are illustrated and discussed herein as comprising the same materials in the second device region 1002 and the first device region 1001 for illustrative purposes only. As such, in some embodiments one or both of the first semiconductor layers and the second semiconductor layers may be different materials or formed in a different order in the first and second device regions 1001 and 1002.

Further in FIG. 6, appropriate wells (not separately illustrated) may be formed in the fin structures 206, the nanostructures 203, and/or the STI regions 208. In some embodiments with different well types in different device regions 1001 and 1002, different implant steps for the first device region 1001 and the second device region 1002 may be achieved using a photoresist or other masks (not separately illustrated). For example, a photoresist may be formed over the fin structures 206 and the STI regions 208 in the first device region 1001 and the second device region 1002. The photoresist is patterned to expose the second device region 1002. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the second device region 1002, and the photoresist may act as a mask to substantially prevent the first impurities from being implanted into the first device region 1001. After the implant, the photoresist is removed, such as by an acceptable ashing process.

Following or prior to the implanting of the second device region 1002, a photoresist or other masks (not separately illustrated) is formed over the fin structures 206, the nanostructures 203, and the STI regions 208 in the first device region 1001 and the second device region 1002. The photoresist is then patterned to expose the first device region 1001. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the first device region 1001, and the photoresist may act as a mask to substantially prevent p-type impurities from being implanted into the second device region 1002. After the implant, the photoresist may be removed, such as by an acceptable ashing process.

After one or more well implants of the first device region 1001 and the second device region 1002, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

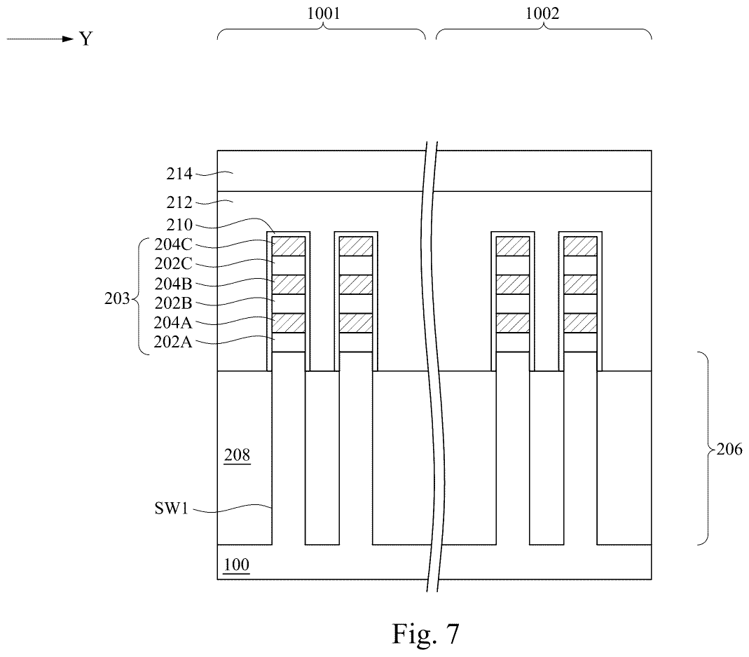

In FIG. 7, a dummy dielectric layer 210 is formed on the fin structures 206 and/or the nanostructures 203. The dummy dielectric layer 210 may be, for example, silicon oxide, silicon nitride, a combination thereof, or the like, and may be deposited or thermally grown according to acceptable techniques. A dummy gate layer 212 is formed over the dummy dielectric layer 210, and a mask layer 214 is formed over the dummy gate layer 212. The dummy gate layer 212 may be deposited over the dummy dielectric layer 210 and then planarized, such as by a CMP. The mask layer 214 may be deposited over the dummy gate layer 212. The dummy gate layer 212 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 212 may be deposited by physical vapor deposition (PVD), CVD, sputter deposition, or other techniques for depositing the selected material. The dummy gate layer 212 may be made of other materials that have a high etching selectivity from the etching of isolation regions. The mask layer 214 may include, for example, silicon nitride, silicon oxynitride, or the like. In this example, a single dummy gate layer 212 and a single mask layer 214 are formed across the first device region 1001 and the second device region 1002. It is noted that the dummy dielectric layer 210 is shown covering only the fin structures 206 and the nanostructures 203 for illustrative purposes only. In some embodiments, the dummy dielectric layer 210 may be deposited such that the dummy dielectric layer 210 covers the STI regions 208, such that the dummy dielectric layer 210 extends between the dummy gate layer 212 and the STI regions 208.

FIGS. 8A through 18B illustrate various following steps in the manufacturing of embodiment devices. FIGS. 9A, 10A, 11A, 12A, 13A, 14A, 14C, 15A, 15C, 16A, 17A and 18A illustrate features in either the first device region 1001 or the second device region 1002. In FIGS. 8A and 8B, the mask layer 214 (see FIG. 7) may be patterned using acceptable photolithography and etching techniques to form masks 218. The pattern of the masks 218 then may be transferred to the dummy gate layer 212 and to the dummy dielectric layer 210 to form dummy gates 216 and dummy gate dielectrics 211, respectively. The dummy gates 216 cover respective channel regions of the fin structures 206. The pattern of the masks 218 may be used to physically separate each of the dummy gates 216 from adjacent dummy gates 216. The dummy gates 216 may also have a lengthwise direction substantially perpendicular to the lengthwise direction of respective fin structures 206.

In FIGS. 9A and 9B, a spacer layer 222 is formed over the structures illustrated in FIGS. 8A and 8B, respectively. The spacer layer 222 will be subsequently patterned to act as spacers for forming self-aligned source/drain regions. In FIGS. 9A and 9B, the spacer layer 222 is formed on top surfaces of the STI regions 208; top surfaces and sidewalls of the fin structures 206, the nanostructures 203, and the masks 218; and sidewalls of the dummy gates 216 and the dummy gate dielectric 211. The spacer layer 222 is formed by atomic layer deposition (ALD), for example, thermal atomic layer deposition or plasma enhanced atomic layer deposition.

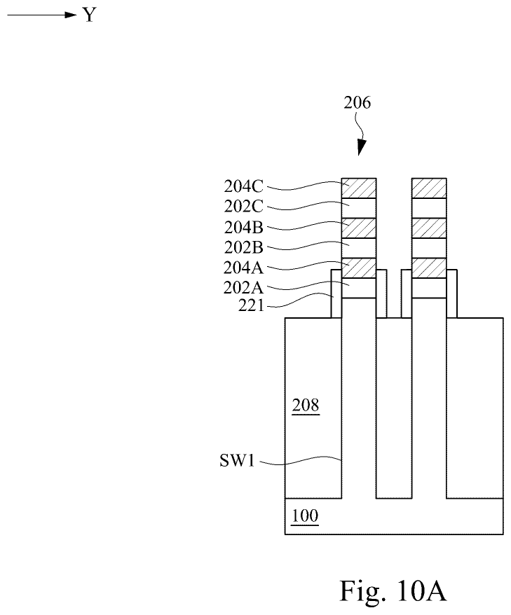

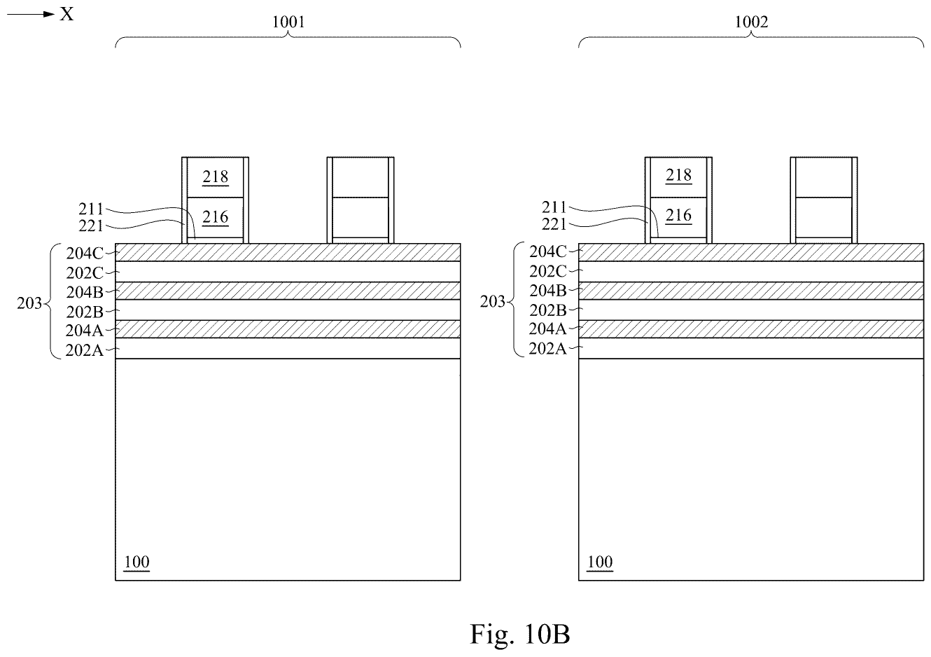

In FIGS. 10A and 10B, the spacer layer 222 is etched to form spacers 221 on opposite sidewalls of the masks 218, dummy gates 216 and dummy gate dielectrics 211. As will be discussed in greater detail below, the spacers 221 act to self-align subsequently formed source drain regions, as well as to protect sidewalls of the fin structures 206 and/or nanostructure 203 during subsequent processing. The spacer layer 222 may be etched using a suitable etching process, such as an isotropic etching process (e.g., a wet etching process), an anisotropic etching process (e.g., a dry etching process), or the like.

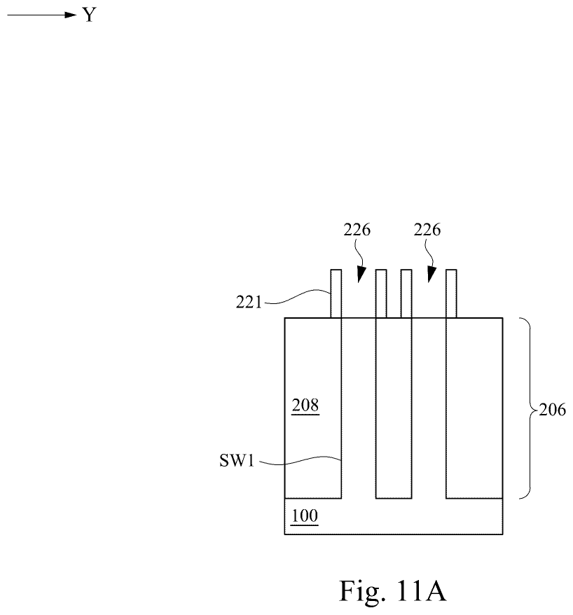

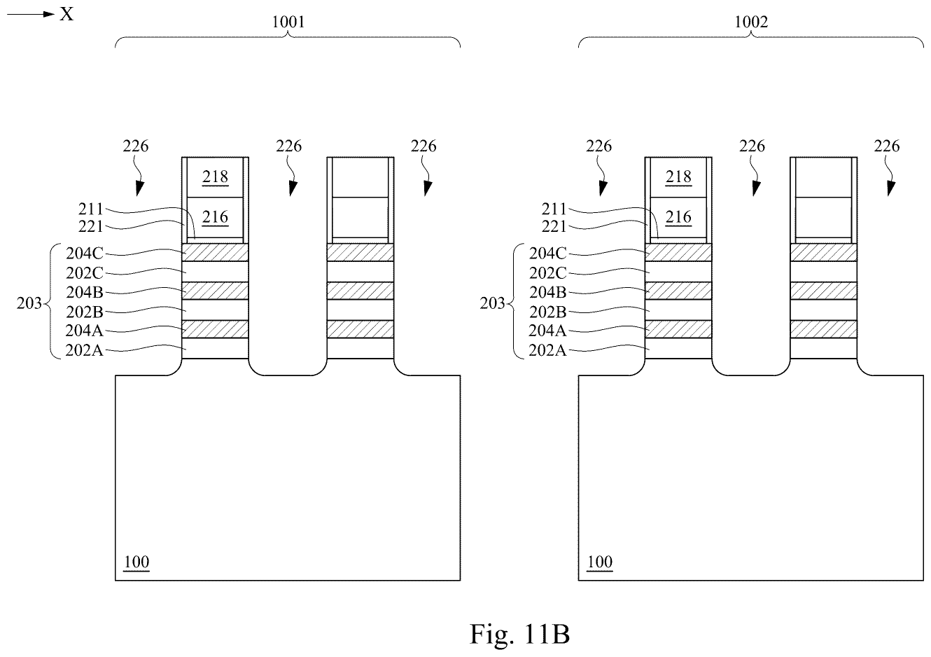

In FIGS. 11A and 11B, source/drain recesses 226 are formed in the fin structures 206, the nanostructures 203, and the substrate 100, in accordance with some embodiments. Epitaxial source/drain regions will be subsequently formed in the source/drain recesses 226. The source/drain recesses 226 may extend through the first nanostructures 202 and the second nanostructures 204, and into the substrate 100. As illustrated in FIG. 11A, bottom surfaces of the source/drain recesses 226 may be level with top surfaces of the STI regions 208, as an example. In some other embodiments, the fin structures 206 may be etched such that bottom surfaces of the source/drain recesses 226 are disposed below the top surfaces of the STI regions 208, or above the top surfaces of the STI regions 208. The source/drain recesses 226 may be formed by etching the fin structures 206, the nanostructures 203, and the substrate 100 using anisotropic etching processes, such as RIE, NBE, or the like. The spacers 221 and the masks 218 mask portions of the fin structures 206, the nanostructures 203, and the substrate 100 during the etching processes used to form the source/drain recesses 226. A single etch process or multiple etch processes may be used to etch each layer of the nanostructures 203 and/or the fin structures 206. Timed etch processes may be used to stop the etching of the source/drain recesses 226 after the source/drain recesses 226 reach a target depth.

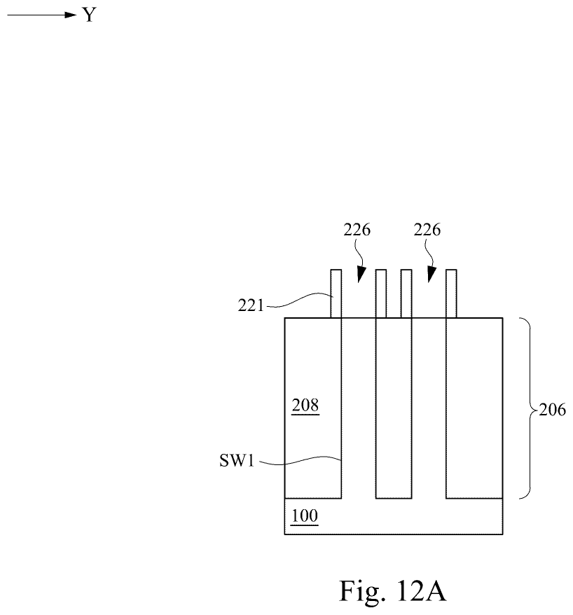

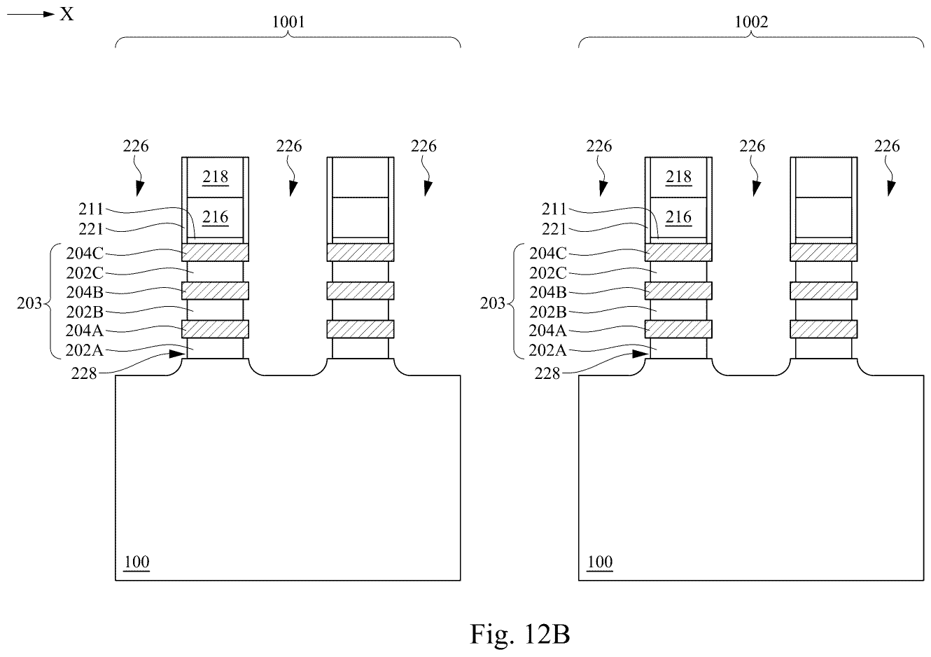

In FIGS. 12A-12B, portions of sidewalls of the layers of the multi-layer stack 201 formed of the first semiconductor materials (e.g., the first nanostructures 202) exposed by the source/drain recesses 226 are etched to form sidewall recesses 228 between corresponding second nanostructures 204. Although sidewalls of the first nanostructures 202 in the sidewall recesses 228 are illustrated as being straight in FIGS. 12A-12B, the sidewalls may be concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202.

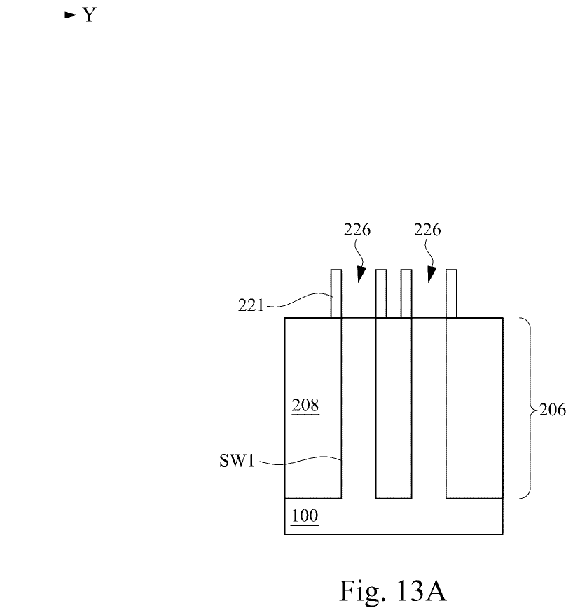

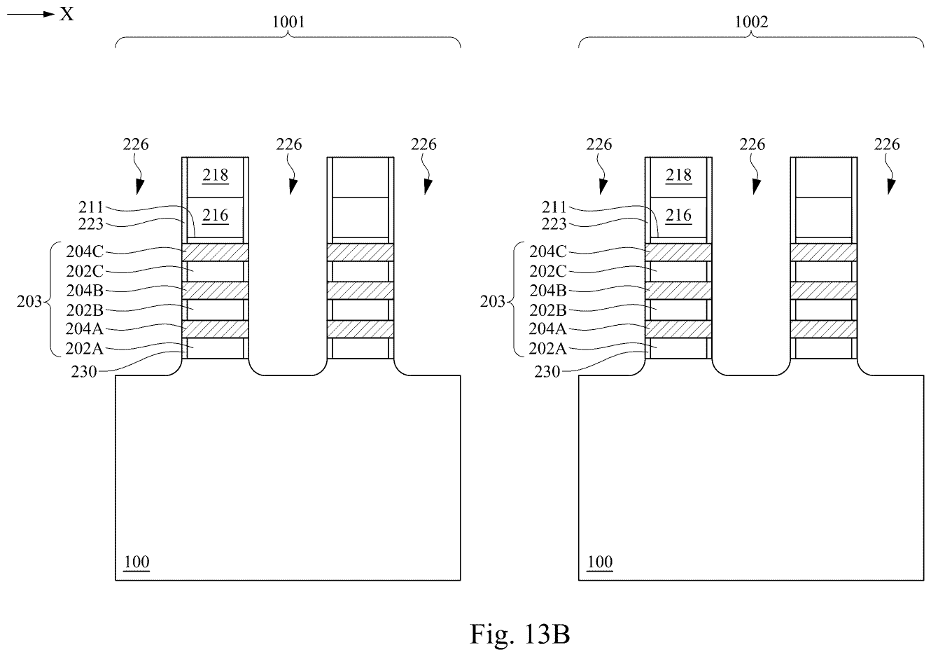

In FIGS. 13A-13B, inner spacers 230 are formed in the sidewall recesses. In some embodiments, the sidewalls of the first semiconductor layers 202A-C may be etched using isotropic etching processes, such as wet etching or the like. In some embodiments in which the first semiconductor layers 202A-C include, e.g., SiGe, and the second semiconductor layers 204A-C include, e.g., Si, a dry etch process with tetramethylammonium hydroxide (TMAH), ammonium hydroxide (NH₄OH), or the like may be used to etch sidewalls of the first semiconductor layers 202A-C.

The inner spacers 230 may be formed by depositing a spacer layer (not shown) by a conformal deposition process, such as CVD, ALD, or the like. The spacer layer may include a material such as silicon nitride or silicon oxynitride, although any suitable material, such as low-dielectric constant (low-k) materials having a k-value less than about 3.5, may be utilized. In particular, the inner spacers 230 may be formed by depositing the spacer layer blanket over the substrate 100 and filling the sidewall recesses of the first semiconductor layers 202A-C, on the fin spacers 223, on the STI regions 208 and on the fin structure 206 exposed by the source/drain recesses 226, and then performing an anisotropic etching to remove unwanted portions of the spacer layer. Although outer sidewalls of the inner spacers 230 are illustrated as being flush with sidewalls of the second semiconductor layers 204A-C, the outer sidewalls of the inner spacers 230 may extend beyond or be recessed from sidewalls of the second semiconductor layers 204A-C.

Reference is made to FIGS. 14A-14E. Source/drain epitaxial structures 232 can be formed in the source/drain recesses 226 (see FIGS. 13A-13B). In some embodiments, the source/drain epitaxial structures 232 may exert stress on the second semiconductor layers 204A-C, thereby improving device performance. In some embodiments, during forming the source/drain epitaxial structures 232, epitaxial patterns 63 may be formed on the sidewalls SW1 of the fin structures 206. In other words, the epitaxial patterns 63 can be formed on an interface between the sidewalls SW1 of the fin structures 206 and the STI regions 208. FIG. 14D shows an enlarged three-dimensional view of a region R1 of FIG. 14C in accordance with some embodiments. The source/drain epitaxial structures 232 are omitted in FIG. 14D for clarity of discussion. In FIG. 14D, since the substrate 100 includes the (110) surface orientation, a first length 45L1 of the trench 45 can extend along a (100) direction. A second length 45L2 of the trench 45 can extend along a (110) direction. Therefore, the epitaxial patterns 63 can have a non-rectangular or a non-circle shape. For example, the epitaxial patterns 63 can have triangular shapes. In some embodiments, the epitaxial patterns 63 can include a first length La, a second length Lb and a third length Lc in which each of the first length La, the second length Lb and the third length Lc can be about 50 nm to about 500 nm. In some embodiments, the first length La, the second length Lb and the third length Lc can be equal. In some other embodiments, at least two of the first length La, the second length Lb and the third length Lc can be different.

In some embodiments, due to the epitaxial patterns 63 growing during forming the source/drain epitaxial structures 232, the epitaxial patterns 63 may include a material same as a material of the source/drain epitaxial structures 232. For example, the source/drain epitaxial structures 232 and the epitaxial patterns 63 both can include Si. In some other embodiments, the source/drain epitaxial structures 232 and the epitaxial patterns 63 both can include SiGe.

In some embodiments, the source/drain epitaxial structures 232 can be formed at a temperature in a range from about 500° C. to about 700° C. such as about 600° C. to about 700° C., at a pressure of about 0.1 torr to about 100 torr, such as about 5 torr to about 20 torr. In some embodiments, a silicon-containing precursor such as SiH₄, Si₂H₆, SiH₂Cl₂, or the like may be used to form the source/drain epitaxial structures 232 and the epitaxial patterns 63 made of silicon. In some embodiments, a silicon-containing precursor such as SiH₄, Si₂H₆, SiH₂Cl₂, or the like and a germanium-containing precursor such as GeH₄ may be used to form the source/drain epitaxial structures 232 and the epitaxial patterns 63 made of silicon germanium. In some embodiments, when the trench 45 is projected to a flat surface, a density of the epitaxial patterns 63 can be more than about 10¹² counts/m².

Reference is made to FIG. 14E. In some embodiments, during forming the source/drain epitaxial structures 232, the epitaxial patterns 63 may also be formed on the sidewalls SW2 of the trenches 47 of the alignment marks AM and on sidewalls of other trenches (not shown) on the substrate 100. In some other embodiments, the epitaxial patterns 63 can also be formed on the boundaries BD2 of the scribe lines 103 (see FIG. 3).

In some embodiments, the source/drain epitaxial structures 232 may include any acceptable material appropriate for n-type GAA-FETs. For example, if the second nanostructures 204 are silicon, the source/drain epitaxial structures 232 may include materials exerting a tensile strain on the second nanostructures 204, such as silicon carbide, phosphorous doped silicon carbide, silicon phosphide, or the like. In some embodiments, the source/drain epitaxial structures 232 may include any acceptable material appropriate for p-type GAA-FETs. For example, if the second nanostructures 204 are silicon, the source/drain epitaxial structures 232 may comprise materials exerting a compressive strain on the second nanostructures 204, such as silicon germanium, boron doped silicon germanium, germanium, germanium tin, or the like. The source/drain epitaxial structures 232 may have surfaces raised from respective upper surfaces of the nanostructures 203 and may have facets.

The source/drain epitaxial structures 232 may be implanted with dopants to form source/drain regions, followed by an anneal. The n-type and/or p-type impurities for source/drain regions may be any of the impurities previously discussed. In some embodiments, the source/drain epitaxial structures 232 may be in situ doped during growth.

As a result of the epitaxy processes used to form the source/drain epitaxial structures 232, upper surfaces of the source/drain epitaxial structures 232 have facets which expand laterally outward beyond sidewalls of the nanostructures 203. In some embodiments, these facets cause adjacent source/drain epitaxial structures 232 to merge as illustrated by FIG. 14A. In some other embodiments, adjacent source/drain epitaxial structures 232 remain separated after the epitaxy process is completed. In the embodiments illustrated in FIG. 14A, the spacers 221 may be formed to a top surface of the STI regions 208 thereby blocking the lateral epitaxial growth. In some other embodiments, the spacers 221 may cover portions of the sidewalls of the nanostructures 203 further blocking the epitaxial growth. In some other embodiments, the spacer etch used to form the spacers 221 may be adjusted to remove the spacer material to allow the epitaxially grown region to extend to the surface of the STI region 208.

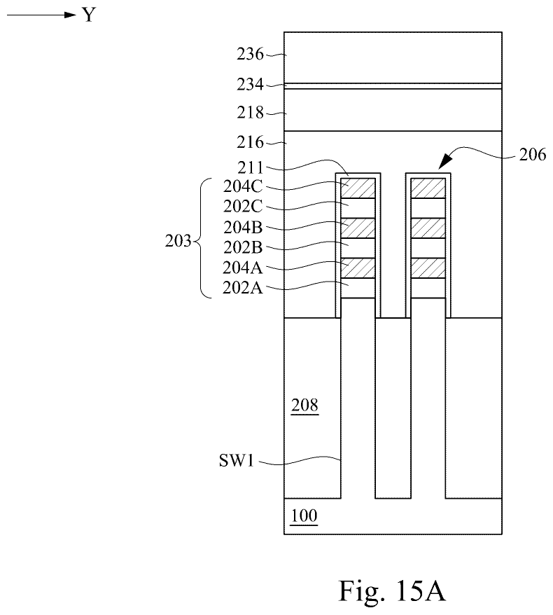

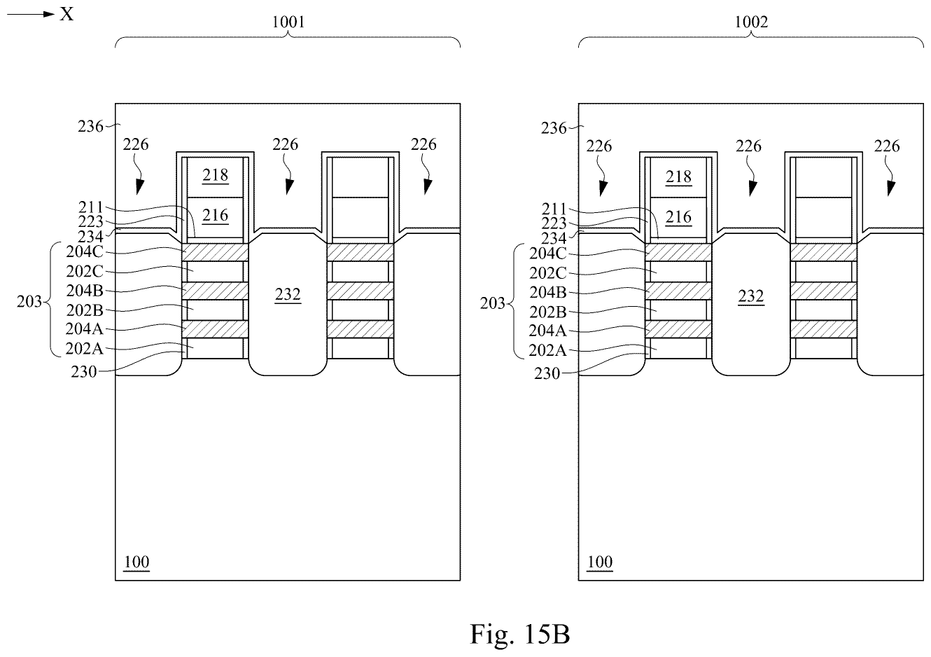

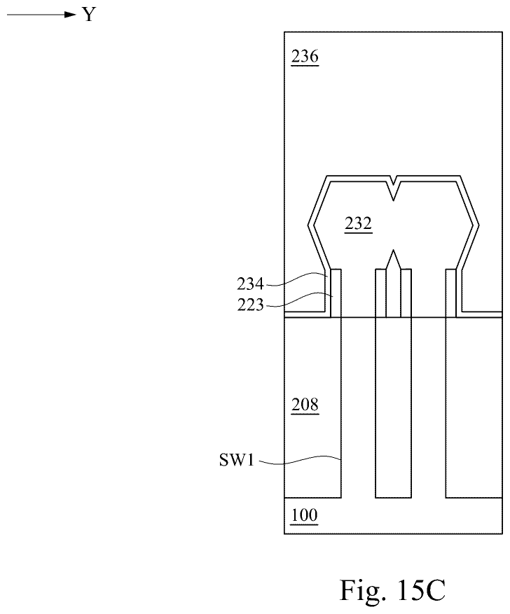

In FIGS. 15A-15C, an interlayer dielectric (ILD) layer 236 is deposited over the structure illustrated in FIGS. 14A-14C. The ILD layer 236 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 234 is disposed between the ILD layer 236 and the source/drain epitaxial structures 232, the masks 218, and the spacers 221. The CESL 234 may comprise a dielectric material, such as, silicon nitride, silicon oxide, silicon oxynitride, or the like, having a different etch rate than the material of the overlying ILD layer 236.

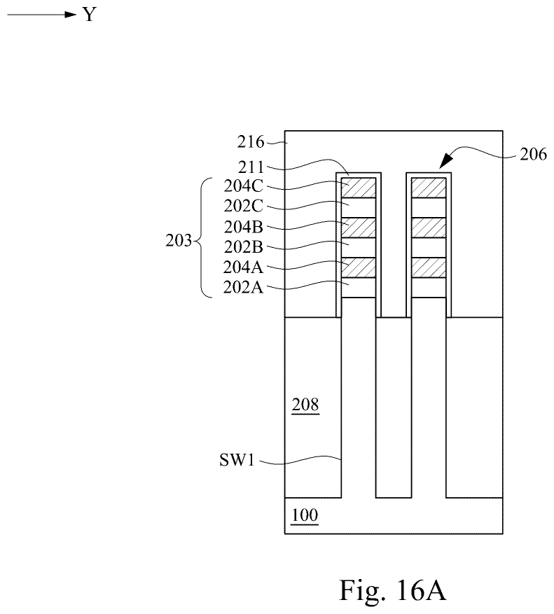

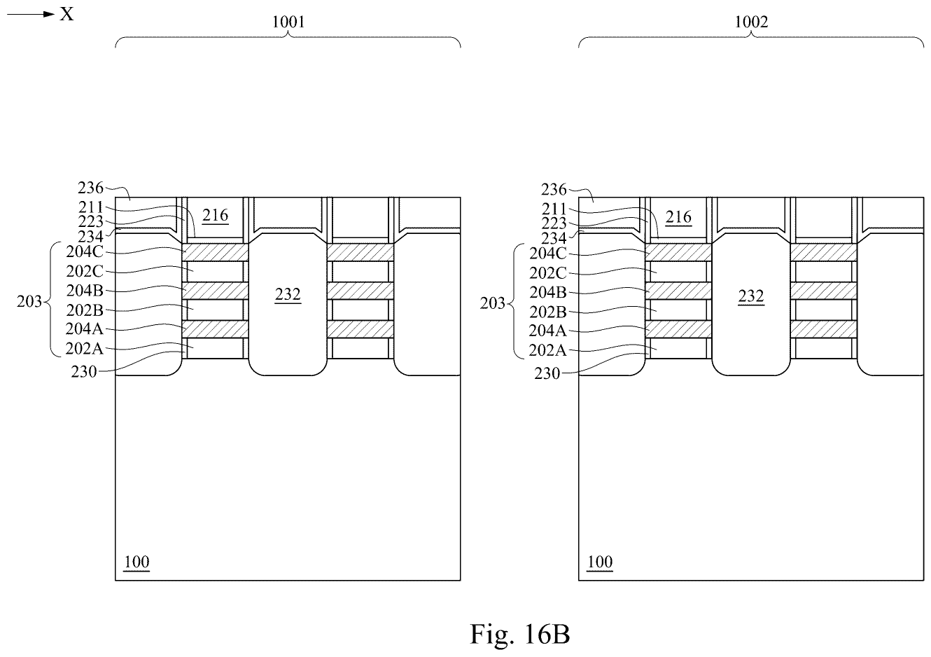

In FIGS. 16A-16B, a planarization process, such as a CMP, may be performed to level the top surface of the ILD layer 236 with the top surfaces of the dummy gates 216 or the masks 218. The planarization process may also remove the masks 218 on the dummy gates 216, and portions of the spacers 221 along sidewalls of the masks 218. After the planarization process, top surfaces of the dummy gates 216, the spacers 221, and the ILD layer 236 are level within process variations. Accordingly, the top surfaces of the dummy gates 216 are exposed through the ILD layer 236. In some embodiments, the masks 218 may remain, in which case the planarization process levels the top surface of the ILD layer 236 with top surface of the masks 218 and the spacers 221.

In FIGS. 16A and 16B, the dummy gates 216, and the masks 218 if present, are removed in one or more etching steps, so that gate trenches 238 are formed between corresponding spacers 221. In some embodiments, portions of the dummy gate dielectrics 211 in the gate trenches 238 are also be removed. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than the ILD layer 236 or the spacers 221. Each gate trench 238 exposes and/or overlies portions of nanostructures 204, which act as channel regions in subsequently completed GAA-FETs. The nanostructures 204 which act as the channel regions are disposed between neighboring pairs of the source/drain epitaxial structures 232. During the removal, the dummy gate dielectrics 211 may be used as etch stop layers when the dummy gates 216 are etched. The dummy gate dielectrics 211 may then be removed after the removal of the dummy gates 216.

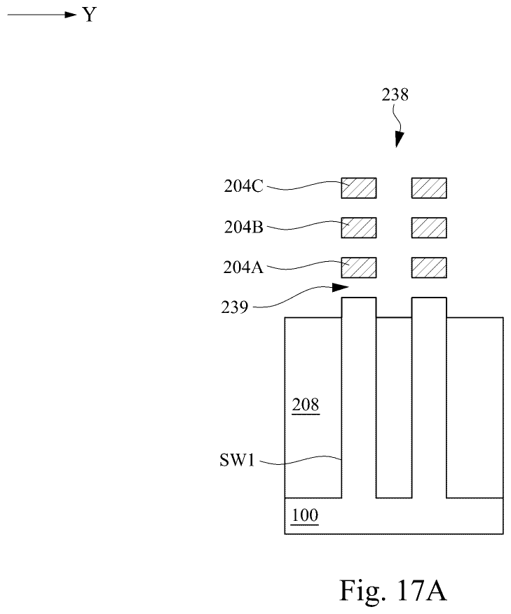

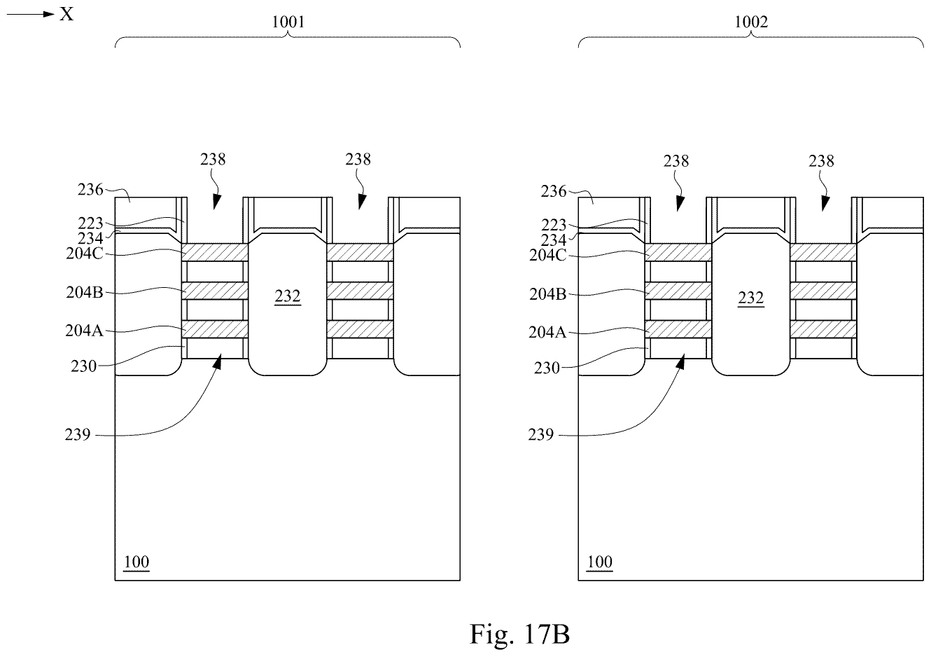

In FIGS. 17A and 17B, the first nanostructures 202 in the gate trenches 238 are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-sheet spaces if the nanostructures 204 are nanosheets). This step can be referred to as a channel release process. The second nanostructures 204 extend in the x-axis above the substrate 100 and spaced apart in the z-axis perpendicular to the x-axis. As illustrated in FIGS. 17A and 17B, gaps 239 (empty spaces) are formed between the second nanostructures 204. At this interim processing step, the gaps 239 between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments the second nanostructures 204 may be trimmed to have a substantial rounded shape (i.e., cylindrical) due to the selective etching process for completely removing the first nanostructures 202. In that case, the resultant second nanostructures 204 can be called nanowires.

In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202. In some embodiments, both the channel release step and the previous step of laterally recessing first nanostructures 202 (i.e., the step as illustrated in FIGS. 12A-12B) use a selective etching process that etches first nanostructures 202 (e.g., SiGe) at a faster etch rate than etching second nanostructures 204 (e.g., Si), and therefore these two steps may use the same etchant chemistry in some embodiments. In this case, the etching time/duration of channel release step is longer than the etching time/duration of the previous step of laterally recessing first nanostructures 202, so as to completely remove the sacrificial nanostructures 202.

Next, in FIGS. 18A and 18B, high-k/metal gate structures are formed. For example, a gate dielectric layer 240 is formed (e.g., conformally) in the gate trenches 238 and in the gaps 239. The gate dielectric layer 240 wraps around the second nanostructures 204, lines sidewalls of the inner spacers 230 and sidewalls of the spacers 221, and extends along the upper surface of the fin structures 206. In accordance with some embodiments, the gate dielectric layer 120 comprises silicon oxide, silicon nitride, or multilayers thereof. In some embodiments, the gate dielectric layer 240 includes a high-k dielectric material, and in these embodiments, the gate dielectric layer 240 may have a dielectric constant greater than about 7.0, and may include a metal oxide or a silicate of Hf, Al, Zr, La, Mg, Ba, Ti, or Pb, or combinations thereof. The formation methods of the gate dielectric layer 240 may include Molecular-Beam Deposition (MBD), ALD, PECVD, and the like.

In an alternative embodiment, an interfacial layer (not shown) is deposited between the gate dielectric layer 240 and the second nanostructures 204 and is formed of silicon oxide or silicon oxynitride grown by a thermal oxidation process. For example, the interfacial layer can be grown by a rapid thermal oxidation (RTO) process or by an annealing process using oxygen.

Next, a gate electrode material (e.g., an electrically conductive material) is formed in the gate trenches 238 and in the gaps 239 to form the gate electrodes 242. The gate electrodes 242 fill the remaining portions of the gate trenches 238 and in the gaps 239. For example, the gate electrodes 242 include one or more work function layers 244 and a fill metal layer 246. A CMP is then performed on the fill metal layer 246, the one or more work function layers 244 and the gate dielectric layer 240 until the ILD layer 236 is exposed, resulting in the fill metal layer 246, the one or more work function layers 244 and the gate dielectric layer 240, the CESL 234, and the ILD layer 236 having substantially level top surfaces. The gate electrodes 242 and the gate dielectric layer 240 are collectively referred to as metal gate structures 248.

The one or more work function layers 244 may be deposited to surround each of the second nanostructures 204. A portion of the one or more work function layers 244 is formed vertically between adjacent second nanostructures 204 and fills the gaps 239 between adjacent second nanostructures 204.

The one or more work function layers can provide a suitable work function for the high-k/metal gate structures. For an n-type GAA FET, the one or more work function layers 244 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the one or more work function layers 244 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal layer 246 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that the present disclosure in various embodiments provides an epitaxial source/drain region formed on the wafer having a (110) surface orientation, and thus the mobility of the P-type device can be boosted. Yet another advantage is that although the (110) wafer would degrade the mobility of n-type device, net mobility on Ring Oscillator (RO) can be improved.

In some embodiments, a method comprises the following steps. A channel region is formed over a substrate, wherein the substrate has a (110) surface orientation and a trench in the substrate. An epitaxial growth is performed to the substrate to form epitaxial source/drain regions on opposite sides of the channel region, wherein first epitaxial patterns are formed on the sidewall of the trench during the epitaxial growth, wherein one of the first epitaxial patterns comprises a triangular shape. A gate is formed surrounding the channel region. In some embodiments, the method further comprises the following step. A semiconductor strip is formed under the channel region. An isolation feature is formed disposed over the substrate and alongside the semiconductor strip. Second epitaxial patterns are formed between the semiconductor strip and the isolation feature. In some embodiments, the second epitaxial patterns, the first epitaxial patterns and the epitaxial source/drain regions comprise the same material. In some embodiments, the second epitaxial patterns, the first epitaxial patterns and the epitaxial source/drain regions comprise Si. In some embodiments, the second epitaxial patterns, the first epitaxial patterns and the epitaxial source/drain regions comprise SiGe. In some embodiments, one of the second epitaxial patterns comprises a triangular shape. In some embodiments, the substrate comprises a plurality of scribe lines, and performing the epitaxial growth to the substrate further comprises forming third epitaxial patterns on a sidewall of the scribe lines. In some embodiments, one of the third epitaxial patterns comprises a triangular shape. In some embodiments, the third epitaxial patterns, the first epitaxial patterns and the epitaxial source/drain regions comprise Si. In some embodiments, the third epitaxial patterns, the first epitaxial patterns and the epitaxial source/drain regions comprise SiGe.

In some embodiments, a method comprises the following steps. A multi-layer stack is formed including alternately stacked channel layers and sacrificial layers stacked in a vertical direction on a semiconductor strip over a substrate, wherein the substrate has a (110) surface orientation. A shallow trench isolation (STI) region is formed alongside the semiconductor strip, wherein the STI regions and the semiconductor strip have an interface therebetween. An epitaxial growth is performed to the substrate to form epitaxial source/drain regions on opposite sides of the channel layers, wherein first epitaxial patterns are formed on the interface between the STI regions and the semiconductor strip during the epitaxial growth, wherein one of the first epitaxial patterns comprises a triangular shape. The sacrificial layers are replaced with a gate stack. In some embodiments, the triangular shape of the one of the first epitaxial patterns has a first length, a second length and a third length, wherein the first length, the second length, and the third length are equal. In some embodiments, the triangular shape of the one of the first epitaxial patterns has a first length, a second length and a third length, wherein at least two of the first, second, and third lengths are different. In some embodiments, the epitaxial source/drain regions and the first epitaxial patterns comprise Si. In some embodiments, the epitaxial source/drain regions and the first epitaxial patterns comprise SiGe. In some embodiments, the substrate further comprises a trench in the substrate, and performing the epitaxial growth to the substrate further comprises forming second epitaxial patterns on a sidewall of the trench, and one of the second epitaxial patterns has a triangular shape. In some embodiments, the second epitaxial patterns and the epitaxial source/drain regions comprise Si. In some embodiments, the second epitaxial patterns and the epitaxial source/drain regions comprise SiGe.

In some embodiments, a semiconductor device comprises a substrate having a (110) surface orientation, a channel region over the substrate, epitaxial source/drain regions on opposite sides of the channel region, a trench in the substrate, first epitaxial patterns on a sidewall of the trench, wherein one of the first epitaxial patterns has a triangular shape, and a gate structure surrounding the channel region. In some embodiments, the trench has a sidewall with a tapered angle with respect to a line parallel to a surface of the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a channel region over a substrate, wherein the substrate has a (110) surface orientation and a trench in the substrate;
performing an epitaxial growth to the substrate to form epitaxial source/drain regions on opposite sides of the channel region, wherein first epitaxial patterns are formed on the sidewall of the trench during the epitaxial growth, wherein one of the first epitaxial patterns comprises a triangular shape; and
forming a gate surrounding the channel region.

2. The method of claim 1, further comprising:
forming a semiconductor strip under the channel region;
forming an isolation feature disposed over the substrate and alongside the semiconductor strip; and
forming second epitaxial patterns between the semiconductor strip and the isolation feature.

3. The method of claim 2, wherein the second epitaxial patterns, the first epitaxial patterns and the epitaxial source/drain regions comprise the same material.

4. The method of claim 2, wherein the second epitaxial patterns, the first epitaxial patterns and the epitaxial source/drain regions comprise Si.

5. The method of claim 2, wherein the second epitaxial patterns, the first epitaxial patterns and the epitaxial source/drain regions comprise SiGe.

6. The method of claim 2, wherein one of the second epitaxial patterns comprises a triangular shape.

7. The method of claim 1, wherein the substrate comprises a plurality of scribe lines, and performing the epitaxial growth to the substrate further comprises:
forming third epitaxial patterns on a sidewall of the scribe lines.

8. The method of claim 7, wherein one of the third epitaxial patterns comprises a triangular shape.

9. The method of claim 7, wherein the third epitaxial patterns, the first epitaxial patterns and the epitaxial source/drain regions comprise Si.

10. The method of claim 7, wherein the third epitaxial patterns, the first epitaxial patterns and the epitaxial source/drain regions comprise SiGe.

11. A method, comprising:
forming a multi-layer stack including alternately stacked channel layers and sacrificial layers stacked in a vertical direction on a semiconductor strip over a substrate, wherein the substrate has a (110) surface orientation;
forming a shallow trench isolation (STI) region alongside the semiconductor strip, wherein the STI regions and the semiconductor strip have an interface therebetween;
performing an epitaxial growth to the substrate to form epitaxial source/drain regions on opposite sides of the channel layers, wherein first epitaxial patterns are formed on the interface between the STI regions and the semiconductor strip during the epitaxial growth, wherein one of the first epitaxial patterns comprises a triangular shape; and
replacing the sacrificial layers with a gate stack.

12. The method of claim 11, wherein the triangular shape of the one of the first epitaxial patterns has a first length, a second length and a third length, wherein the first length, the second length, and the third length are equal.

13. The method of claim 11, wherein the triangular shape of the one of the first epitaxial patterns has a first length, a second length and a third length, wherein at least two of the first, second, and third lengths are different.

14. The method of claim 11, wherein the epitaxial source/drain regions and the first epitaxial patterns comprise Si.

15. The method of claim 11, wherein the epitaxial source/drain regions and the first epitaxial patterns comprise SiGe.

16. The method of claim 11, wherein the substrate further comprises a trench in the substrate, and performing the epitaxial growth to the substrate further comprises forming second epitaxial patterns on a sidewall of the trench, and one of the second epitaxial patterns has a triangular shape.

17. The method of claim 16, wherein the second epitaxial patterns and the epitaxial source/drain regions comprise Si.

18. The method of claim 16, wherein the second epitaxial patterns and the epitaxial source/drain regions comprise SiGe.

19. A semiconductor device, comprising:
a substrate having a (110) surface orientation;
a channel region over the substrate;
epitaxial source/drain regions on opposite sides of the channel region;
a trench in the substrate;
first epitaxial patterns on a sidewall of the trench, wherein one of the first epitaxial patterns has a triangular shape; and
a gate structure surrounding the channel region.

20. The semiconductor device of claim 19, wherein the trench has a sidewall with a tapered angle with respect to a line parallel to a surface of the substrate.
